(19) United States
(12) Patent Application Publication
(10) Pub. No.: US 2010/0006924 A1
(43) Pub. Date: Jan. 14, 2010

(54) ONE-TIME PROGRAMMABLE READ-ONLY MEMORY

(75) Inventors: Hsin-Ming Chen, Tainan County (TW); Shao-Chang Huang, Hsinchu City (TW); Shih-Chen Wang, Taipei City (TW); Tsung-Mu Lai, Hsinchu County (TW); Ming-Chou Ho, Hsinchu City (TW); Chrong-Jung Lin, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: EMEMORY TECHNOLOGY INC., Hsin-chu (TW)

(21) Appl. No.: 12/171,301

(22) Filed: Jul. 11, 2008

(51) Int. Cl. H01L 27/112

(52) U.S. Cl. 257/326; 257/E27.102

(57) ABSTRACT

A one-time programmable read-only memory (OTP-ROM) including a substrate, a first doped region, a second doped region, a third doped region, a first dielectric layer, a select gate, a second dielectric layer, a first channel, a second channel and a silicide layer is provided. The first doped region, the second doped region and the third doped region are disposed apart in a substrate. The first dielectric layer is disposed on the substrate between the first doped region and the second doped region. The select gate is disposed on the first dielectric layer. The second dielectric layer is disposed on the substrate between the second doped region and the third doped region. The silicide layer is disposed on the first doped region, the second doped region and the third doped region. The OTP-ROM stores data by a punch-through effect occurring between the second doped region and the third doped region.

### BACKGROUND OF THE INVENTION

1. Field of the Invention

The present invention relates to a memory, and particularly to a one-time programmable read-only memory (OTP-ROM).

2. Description of Related Art

As the capacity of microprocessors continues to expand and the amount of computation in a given software program keeps getting larger, the requirements for a memory continue growing as well. Consequently, how to fabricate inexpensive high density memories catering to the requirements has become a major concern for the semiconductor manufacturers. According to the difference in reading/writing functions, memories can be simply classified into two types: read only memory (ROM) and random access memory (RAM). A ROM can only do “reading” while a RAM has dual functions of “reading” and “writing”. According to the ways in which data are stored in a ROM, ROMs are generally subdivided into mask ROM, programmable ROM (PROM), erasable programmable ROM (EPROM) and electrically erasable programmable ROM (EEPROM), whereas RAMs are subdivided into static RAM (SRAM) and dynamic RAM (DRAM) according to the ways in which data are processed in a RAM.

In the semiconductor integrated circuit apparatus, the OTP-ROM, whose stored data would not be lost even if the power supply drops, has become an indispensable element in recent years. OTP-ROMs can be extensively applied in the redundancy of the so-called high density memories such as DRAMs or SRAMs, the tuning of the analog circuit, the code storage function for low keys, or in the data storage chip identification (ID) function for management purposes such as the proceedings of the fabricating process.

### SUMMARY OF THE INVENTION

In view of the aforementioned, the present invention provides an OTP-ROM, which is a new form of memory and can effectively store data.

The present invention provides an OTP-ROM including a substrate, a first doped region, a second doped region, a third doped region, a first dielectric layer, a select gate, a second dielectric layer, a first channel, a second channel and a silicide layer. The substrate is a first conductivity type. The first doped region, the second doped region and the third doped region are a second conductivity type and disposed apart in a substrate. The first dielectric layer is disposed on the substrate between the first doped region and the second doped region. The select gate is disposed on the first dielectric layer. The second dielectric layer is disposed on the substrate between the second doped region and the third doped region. The first channel is located in the substrate under the first dielectric layer. The second channel is located in the substrate under the second dielectric layer. The silicide layer is disposed on the first doped region, the second doped region and the third doped region. The OTP-ROM stores data through a punch-through effect between the second doped region and the third doped region.

According to one embodiment of the present invention, the OTP-ROM further includes a charge storage layer disposed on the second dielectric layer.

According to one embodiment of the present invention, in the OTP-ROM, a material of the charge storage layer includes polysilicon.

According to one embodiment of the present invention, in the OTP-ROM, a material of the charge storage layer includes silicon nitride, silicon oxynitride, or other dielectric materials capable to store electrical charges within.

According to one embodiment of the present invention, the OTP-ROM further includes a voltage coupling layer disposed on the second dielectric layer.

According to one embodiment of the present invention, in the OTP-ROM, a material of the voltage coupling layer includes polysilicon, metal, metal oxide, or metal silicide.

According to one embodiment of the present invention, in the OTP-ROM, the first conductivity type and the second conductivity type are different conductivity types.

According to one embodiment of the present invention, in the OTP-ROM, the first doped region, the second doped region and the third doped region are doped with N-type dopants or P-type dopants.

According to one embodiment of the present invention, in the OTP-ROM, a material of the first dielectric layer includes silicon oxide.

According to one embodiment of the present invention, in the OTP-ROM, a material of the select gate includes polysilicon.

According to one embodiment of the present invention, in the OTP-ROM, a material of the second dielectric layer includes silicon oxide.

According to one embodiment of the present invention, in the OTP-ROM, a thickness of the first dielectric layer is larger than a thickness of the second dielectric layer.

According to one embodiment of the present invention, in the OTP-ROM, a thickness of the first dielectric layer is equal to a thickness of the second dielectric layer.

In view of the above-mentioned, the OTP-ROM of the present invention may generate a punch-through effect between the second doped region and the third doped region to store data by applying voltages to the first doped region and the third doped region and render the second doped region floating.

In addition, when a charge storage layer is disposed on the second dielectric layer, under a condition that there are charges stored in the charge storage layer, an operational voltage can be lowered. When charges are stored in the charge storage layer, a phenomenon of breakdown in the second dielectric layer can be avoided so as to effectively elevate an “on-current (Iₒₙ)”.

In another aspect, the OTP-ROM provided by the present invention has a select gate, and therefore the flow of the current can be effectively controlled so as to facilitate accurate data storage without severe programming disturbance. Furthermore, when reading the OTP-ROM, the select gate can also prevent false access of the data.

Moreover, the OTP-ROM of the present invention can be implemented by a current fabricating process without additional masking steps, and hence fully compatible to the existing fabricating process.

In order to the make aforementioned and other objects, features and advantages of the present invention more comprehensible, preferred embodiments accompanied with figures are described in detail below.

### BRIEF DESCRIPTION OF THE DRAWINGS

FIG. 1 illustrates a cross-sectional view of the one-time programmable read-only memory (OTP-ROM) according to the first embodiment of the present invention.

FIG. 2 illustrates a cross-sectional view of the OTP-ROM according to the second embodiment of the present invention.

FIG. 3 illustrates a cross-sectional view of the OTP-ROM according to the third embodiment of the present invention.

FIG. 4 illustrates a curve diagram of the relationship among the drain-to-source current, the drain-to-source current voltage and punch-through voltage of the present invention.

### DESCRIPTION OF EMBODIMENTS

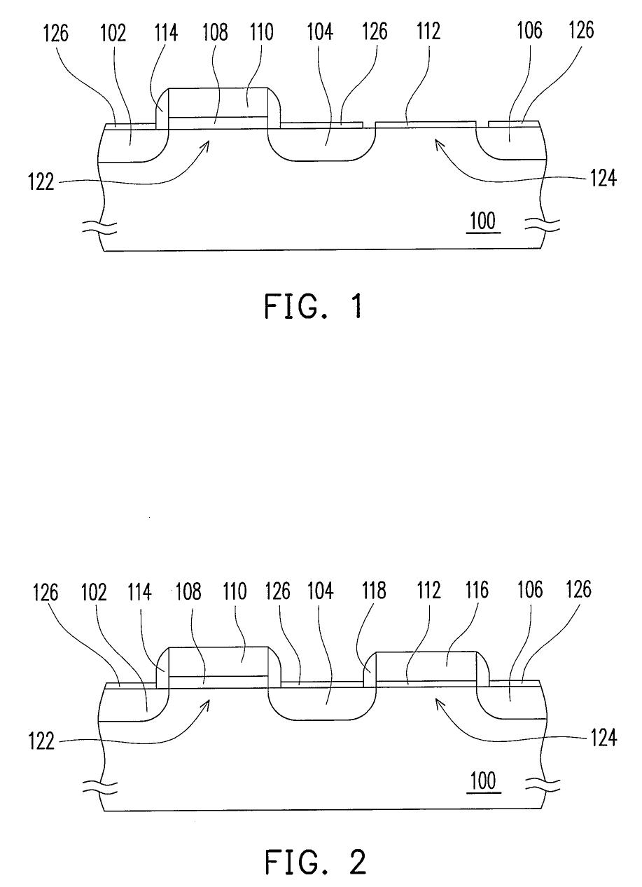

FIG. 1 illustrates a cross-sectional view of the one-time programmable read-only memory (OTP-ROM) according to the first embodiment of the present invention.

Referring to FIG. 1, the OTP-ROM includes a substrate 100, a doped region 102, a doped region 104, a doped region 106, a dielectric layer 108, a select gate 110 and a dielectric layer 112, a channel 122, a channel 124 and a silicide layer 126. The substrate 100 is a first conductivity type. The doped region 102, the doped region 104 and the doped region 106 are a second conductivity type and disposed apart in a substrate 100. The first conductivity type and the second conductivity type are different conductivity types, for example. The first conductivity type and the second conductivity type are either N-type dopants or P-type dopants. In the present embodiment, the first conductivity type is designated N-type dopants and the second conductivity type is designated N-type dopants for an example to facilitate subsequent explication. The method of forming the doped region 102, the doped region 104 and the doped region 106 is performing an ion implantation process, for example.

The dielectric layer 108 is disposed on the substrate 100 between the doped region 102 and the doped region 104 to serve as a gate dielectric layer. The dielectric layer 108 is fabricated using silicon oxide, for example. A method of forming the dielectric layer 108 is performing a thermal oxidation process, for example.

The select gate 110 is disposed on the dielectric layer 108. The select gate 110 is fabricated using polysilicon, for example. A method of forming the select gate is, for example, performing a chemical vapor deposition (CVD) process. Additionally, spacers 114 may be disposed at two sides of the select gate 110. The spacers 114 are fabricated using silicon nitride, for example.

The dielectric layer 112 is disposed on the substrate 100 between the doped region 104 and the doped region 106. The dielectric layer 112 is fabricated using silicon oxide, for example. A method of forming the dielectric layer 112 is performing a thermal oxidation process, for example. A thickness of the dielectric layer 108 may be larger than or equal to a thickness of the dielectric layer 112. In the present embodiment, the thickness of the dielectric layer 108 larger than that of the dielectric layer 112 serves as an example to facilitate subsequent explication. Generally, a transistor with a thicker gate dielectric layer is called an input-output device (I/O device), and a transistor with a thinner gate dielectric layer is called a core device. Another key feature for this present invention is to have spaces apart of dope regions 104 and 106. This feature can be achieved by using the mask definition of these two spaces apart of the doped regions 104 and 106. A gateless MOS transistor is formed according to the above mentioned invention.

The channel 122 is located in the substrate 100 under the dielectric layer 108. The channel 124 is located in the substrate 100 under the dielectric layer 112. The silicide layer 126 is disposed on the doped region 102, the doped region 104 and the doped region 106.

An operation method provided by the OTP-ROM of the present embodiment is applying voltages to the doped region 102 and the doped region 106 and rendering the doped region 104 floating. When the bias difference between the doped region 102 and the doped region 106 is built sufficiently large, a certain current start to flow through a path between the doped region 104 and the doped region 106 due to the punch-through effect. When the current is large enough, a self-heating process on the path will get more and more increased until its thermal run-away. As in the self-heating process, when the junction temperature reaches some critical point, the silicide layer 126 on the doped region 104 and the doped region 106 start to be melted and flow along the current path, following the current flow direction. As the process continues, the silicide layer 126 distribute along the current path between region 104 and 106, and hence gradually link the doped region 104 and the doped region 106 with comparably low resistance to the initial one. This is so-called silicide bridging. And the process can make the device destructive and serve as a programming mechanism.

Furthermore, the select gate 110 can effectively control the flow of the current to facilitate accurate data storage. When reading the OTP-ROM, the select gate 110 can also prevent false access of the data.

In another aspect, the OTP-ROM of the present embodiment can be implemented by a current fabricating process without additional masking steps, and therefore fully compatible to the existing fabricating process.

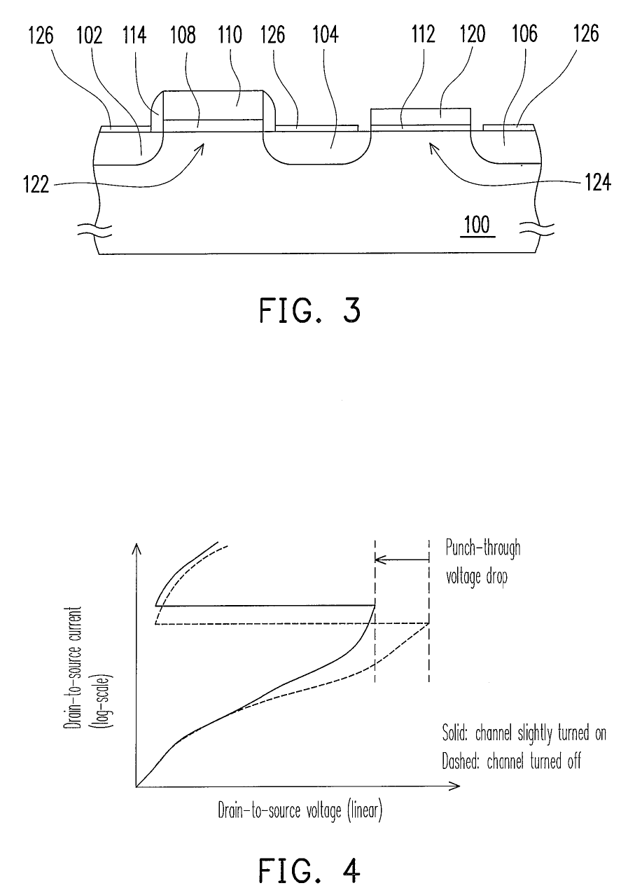

In other embodiments, a charge storage layer may be further disposed on the dielectric layer 112 in the OTP-ROM so as to further improve the efficiency of the OTP-ROM. The following explication refers to FIGS. 2 and 3.

FIG. 2 illustrates a cross-sectional view of the OTP-ROM according to the second embodiment of the present invention. FIG. 3 illustrates a cross-sectional view of the OTP-ROM according to the third embodiment of the present invention. In FIGS. 2 and 3, identical reference numerals are used for the same elements as those in FIG. 1, and description of those elements is omitted.

The primary difference between the embodiments disclosed by FIGS. 2 and 3 and the embodiment disclosed by FIG. 1 lies in that there is a charge storage layer on the dielectric layer 112. Wherein, the material of charge storage layer includes a conductive material or a dielectric material. If the material of charge storage layer is the conductive material, the charge storage layer could be used as a voltage coupling layer. The material of the voltage coupling layer includes polysilicon, metal, metal oxide, or metal silicide.

Referring to FIG. 2, the charge storage layer disposed on the dielectric layer 112 is, for example, a floating gate 116. The floating gate 116 is fabricated using polysilicon, for example. The method of forming the floating gate 116 is, for example, performing a CVD process. Additionally, spacers 118 may be disposed at two sides of the floating gate 116. The spacers 118 are fabricated using silicon nitride, for example.

Referring to FIG. 3, the charge storage layer disposed on the dielectric layer 112 is, for example, a charge storage layer 120. The charge storage layer 120 is fabricated using silicon nitride, for example. The charge storage layer 120 is formed by a CVD process, for example. In standard normal CMOS process, there will be a contact etching stop layer (often using the silicon nitride or oxynitride) to serve as a etching stop layer when doing the contact etching process step. This process also serves as the charge storage layer 120.

Referring to FIGS. 2, when operating the OTP-ROM, programming voltage couples to the floating gate 116 slightly turn on the channel 124 between the doped region 104 and the doped region 106; moreover, the floating gate 116 may receive injected channel hot carriers so as to turn on the channel 124 more. An operational voltage required for generating a punch-through effect between the doped region 104 and the doped region 106 can be thus lowered with the help of voltage coupling or injected carriers, that is so called the voltage coupling effect.

And referring to FIG. 3, when operating the OTP-ROM, the floating gate is slightly coupled by the region 106, channel hot carriers may be injected to the charge storage layer 120 so as to slightly turn on the channel 124 between the doped region 104 and the doped region 106. An operational voltage required for generating a punch-through effect between the doped region 104 and the doped region 106 can be thus lowered. Moreover, since the charge storage layer 120 only needs to help lower the triggering voltage, it would not be required to retain injected charges after programming. Furthermore, if the charge storage layer 120 and the dielectric layer 112 form a nitride gate, the advantage of storing the charges could be achieved. Therefore, a breakdown occurring in a dielectric layer 112 because of the localized damage on 112 could not affect the on-state of the channel 124.

FIG. 4 illustrates a curve diagram of the relationship among the drain-to-source current, the drain-to-source current voltage and punch-through voltage of the present invention.

Referring to FIGS. 4, the solid line represents the situation of the channel 124 slightly turned on, and the dashed line represents the situation of the channel 124 turned off. Obviously, if the channel 124 is slightly turned on, the triggering voltage of punch-through effect.

Moreover, when there are charges stored in the charge storage layer 120 of FIG. 3, a breakdown occurring in a dielectric layer 112 can be neglected because of the localized damage on 112, so that the level of an “on-current (Iₒₙ)” or the programming efficiency of such Iₒₙ could be effectively elevated with the help of higher programming voltage, and hence a conduction current window of the Iₒₙ towards an “off-current (I_{off})” is improved as well.

In summary, the present invention has at least the following advantages.

The OTP-ROM provided by the present invention effectively stores data.

When there are charges stored in the charge storage layer in the OTP-ROM provided by the present invention, the operational voltage of the OTP-ROM is lowered and the Iₒₙ is effectively elevated.

In the OTP-ROM of the present invention, the select gate effectively controls the flow of the current and accurately stores data.

When the OTP-ROM provided by the present invention is reading data, it can avoid false access of the data.

The OTP-ROM of the present invention can be fabricated in the current fabricating process without any additional masking steps. The cost can be further reduced, especially for the advanced CMOS process.

Although the present invention has been disclosed above by the preferred embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A one-time programmable read-only memory (OTP-ROM), comprising:
a substrate of a first conductivity type;
a first doped region, a second doped region and a third doped region of a second conductivity type disposed apart in the substrate;
a first dielectric layer, disposed on the substrate between the first doped region and the second doped region;
a select gate, disposed on the first dielectric layer; and
a second dielectric layer, disposed on the substrate between the second doped region and the third doped region;
a first channel, located in the substrate under the first dielectric layer; and
a second channel, located in the substrate under the second dielectric layer; and
a silicide layer, disposed on the first doped region, the second doped region and the third doped region, wherein
the OTP-ROM stores data through a punch-through effect between the second doped region and the third doped region.

2. The OTP-ROM of claim 1, further comprising a charge storage layer disposed on the second dielectric layer.

3. The OTP-ROM of claim 2, wherein a material of the charge storage layer comprises polysilicon.

4. The OTP-ROM of claim 2, wherein a material of the charge storage layer comprises silicon nitride.

5. The OTP-ROM of claim 1, further comprising a voltage coupling layer disposed on the second dielectric layer.

6. The OTP-ROM of claim 5, wherein a material of the voltage coupling layer comprises polysilicon, metal, metal oxide, or metal silicide.

7. The OTP-ROM of claim 1, wherein the first conductivity type and the second conductivity type are different conductivity types.

8. The OTP-ROM of claim 7, wherein the first doped region, the second doped region and the third doped region are doped with N-type dopants or P-type dopants.

9. The OTP-ROM of claim 1, wherein a material of the first dielectric layer comprises silicon oxide.

10. The OTP-ROM of claim 1, wherein a material of the select gate comprises polysilicon.

11. The OTP-ROM of claim 1, wherein a material of the second dielectric layer comprises silicon oxide.

12. The OTP-ROM of claim 1, wherein a thickness of the first dielectric layer is larger than a thickness of the second dielectric layer.

13. The OTP-ROM of claim 1, wherein a thickness of the first dielectric layer is equal to a thickness of the second dielectric layer.
